(19) United States
(12) Patent Application Publication
(10) Pub. No.: US 2026/0114246 A1
(43) Pub. Date: Apr. 23, 2026

(54) FABRICATION METHODS OF SEMICONDUCTOR STRUCTURES

(71) Applicant: Semiconductor Manufacturing International (Shanghai) Corporation, Shanghai (CN)

(72) Inventor: Jisong JIN, Shanghai (CN)

(21) Appl. No.: 19/363,090

(22) Filed: Oct. 20, 2025

(30) Foreign Application Priority Data
Oct. 18, 2024 (CN) 202411466050.9

(51) Int. Cl. H01L 21/033; H01L 21/027; H01L 21/311; H01L 21/3115; H01L 21/3213; H10B 10/00

(52) U.S. Cl. CPC H10P 76/4085; H10B 10/12; H10B 10/18; H10P 30/40; H10P 50/266; H10P 50/283; H10P 50/667; H10P 50/71; H10P 50/73; H10P 76/2043; H10P 76/405

(57) ABSTRACT

A method for forming a semiconductor structure includes providing a base with a first area and a second area; patterning a first core material layer and forming first core layers; forming first spacers; patterning a second core material layer and forming second core layers; modifying the second core layers exposed in the second area to form third core layers having an etching selectivity ratio with remaining second core layers; forming second spacers covering sidewalls of the second core layers and third core layers; and patterning a target material layer using the second spacers and third core layers as a mask and forming first target structures and second target structures. The pitch of adjacent first target structures is less than or equal to the pitch of adjacent second target structures. SAQP and SALELE processes are integrated. Redundant first target structures made by SAQP are removed without adding masks and process steps.

### CROSS-REFERENCE TO RELATED APPLICATION

This application claims the priority of Chinese Patent Application No. CN 202411466050.9, filed on Oct. 18, 2024, the entire content of which is incorporated herein by reference.

### FIELD OF THE DISCLOSURE

The present disclosure generally relates to the field of semiconductor fabrication technology and, more particularly, relates to semiconductor devices and fabrication methods thereof.

### BACKGROUND

With the rapid advance of semiconductor manufacturing technologies, semiconductor devices are developing towards higher component density and higher integration. Photolithography technology is a commonly used patterning method and the most critical production technology in semiconductor manufacturing processes. Along with continuous reduction of pattern critical dimension (CD) and pitch, self-aligned double patterning (SADP) may no longer meet current process requirements, and self-aligned quadruple patterning (SAQP) method comes into being. Generally, the minimum pitch that SADP may form with the deep ultraviolet (DUV) technology is about half of the pitch limit of 76 nm for a single DUV exposure, which is a pitch of 38 nm. As such, the limit of SAQP with the DUV technology is a pitch of 19 nm. When a good yield is ensured, the general SADP limit is around 40 nm, and the SAQP limit is around 24 nm. In the back-end process, the SADP or SAQP process is often not used to form metal patterns, while self-aligned litho-etch litho-etch or spacer assisted litho-etch litho-etch (SALELE) is often used. SALELE has the advantage of more design freedom than SADP, but the metal pitch limit is similar to SADP, and the minimum pitch may only be about 40 nm.

However, as the size of transistors and chips shrinks, the back-end metal pitch also needs to reach a value of smaller than 40 nm to 30 nm or even a smaller pitch. The traditional SAQP method may achieve smaller pitches, but like SADP, it has major limitations in metal line layout design. Metal line layout generally needs to take into account both smaller pitches and large pitches on the same chip, as well as design freedom such as freely placed metal line positions, which is difficult to achieve using purely the SAQP process. However, in the absence of extreme ultraviolet (EUV) exposure processing, it is relatively difficult to achieve both pitch reduction and design freedom through the SAQP process that only uses the DUV lithography. It also has great limitations on production of chips with more advanced processes.

In the 2015 Society of Photo-Optical Instrumentation Engineers (SPIE) conference paper “Impact of a SADP flow on the design and process for N10/N7 Metal” doi: 10.1117/12.2085923, harms caused by redundant metal lines and methods of removing them in an SADP process are elaborated in detail. However, the paper primarily uses additional masks to remove the extra metal lines, as shown in FIG. 33. A target structure with redundant metal lines removed is shown in part (a) of FIG. 33. However, with only a cut process, the paper retains all redundant metal lines in the final structure, as shown in part (b) of FIG. 33. Therefore, it is known that processes similar to SADP and SAQP, while capable of forming dense patterns, often result in the most tightly packed arrangements, meaning many redundant metal lines will exist. These metal lines do not participate in transistor interconnecting, but are difficult to remove without adding masks. It affects the capacitance between adjacent metal lines used for interconnects.

### SUMMARY OF THE DISCLOSURE

The problem solved by embodiments of the present disclosure is to provide a method for forming a semiconductor structure, which improves the design freedom in patterning processes and may also remove redundant first target structures in the first area.

To solve the above problems, embodiments of the present disclosure provide a method for forming semiconductor structures. The method includes providing a base, wherein the base includes a substrate and a target material layer on the substrate, a second core material layer is formed on the substrate, a first core material layer is formed on the second core material layer, the base further includes a first area for forming first target structures and a second area for forming second target structures, the first target structures and the second target structures all extend along a first direction, and a pitch of adjacent first target structures is less than or equal to a pitch of adjacent second target structures; patterning the first core material layer and forming first core layers that are separate in the first area, extend along the first direction, and are arranged in parallel along a second direction, wherein the first direction is perpendicular to the second direction; forming first spacers covering sidewalls of the first core layers; removing the first core layers; forming a first protective layer on the second core material layer in the second area, wherein first protective layer openings are formed that are separate in the first protective layer, extend along the first direction, and are arranged in parallel along the second direction; patterning the second core material layer using the first spacers and the first protective layer as a mask and forming second core layers; removing the first spacers and the first protective layer; forming second protective layers on the second core layers, wherein the second protective layers are separate in the second area; using the second protective layers as a mask to modify the second core layers exposed in the second area and forming third core layers having an etching selectivity ratio with the remaining second core layers; removing the second protective layers; forming second spacers covering sidewalls of the second core layers and the third core layers; removing the second core layers; and using the second spacers and the third core layers as a mask to pattern the target material layer and forming first target structures in the first area and second target structures in the second area.

Compared with the prior art, the technical solution of embodiments of the present disclosure has the following advantages:
In the formation method provided by embodiments of the present disclosure, the base includes the first area for forming the first target structures, and the second area for forming the second target structures. The pitch of adjacent first target structures is less than or equal to the pitch of adjacent second target structures. The target material layer is patterned with the second spacers and the third core layers as a mask. The first target structures in the first area and the second target structures in the second area are formed. In embodiments of the present disclosure, the first core layers are formed in the first area. The first spacers are formed to cover sidewalls of the first core layers. The first protective layer is formed on the second core material layer in the second area. The first protective layer is formed with first protective layer openings that are separate, extend along the first direction, and are arranged in parallel along the second direction. The second core material layer is patterned with the first spacers and the first protective layer as a mask to form the second core layers. For the first area, the second spacers covering sidewalls of the second core layers are formed, and the target material layer is patterned with the second spacers as a mask, which uses SAQP. The SAQP process may form first target structures with a smaller pitch. For the second area, potions of the second core layers in the second area are modified using the second protective layer as a mask, and the portions of the second core layers are transformed into the third core layers having an etching selectivity ratio with the second core layers. The second spacers covering sidewalls of the second core layers and the third core layers are formed. The second spacers and the third core layers are used as a mask to pattern the target material layer. SALELE is used in the above processes. The second target structures with a larger pitch may be formed using SALELE. Embodiments of the present disclosure may integrate the SAQP process and the SALELE process, and form the first target structures with a smaller pitch and the second target structures with a larger pitch over the same base. It is conducive to meeting more semiconductor process requirements through process integration and improving the design freedom in patterning processes.

Optionally, in the step of forming the second protective layers on the second core layers, the second protective layer openings exposing the second core layers are formed in the second protective layers in the first area. The second protective layer openings extend along the first direction. In the step of modifying the second core layers exposed in the second area using the second protective layers as a mask, the second core layers exposed by the second protective layer openings in the first area are also modified. The third core layers in the second area are formed. In embodiments of the present disclosure, the third core layers are also formed in the first area. When the target material layer is patterned using the second spacers and the third core layers as a mask, the target material layer corresponding to the third core layers in the first area is retained to block formation of part of the first target structures. Therefore, in embodiments of the present disclosure, part of redundant first target structures in the first area made by SAQP may be removed without adding a mask and process steps.

### BRIEF DESCRIPTION OF THE DRAWINGS

The following drawings are merely examples for illustrative purposes according to various disclosed embodiments and are not intended to limit the scope of the present disclosure.

FIGS. 1 to 32 illustrate schematic structural diagrams corresponding to steps in methods for forming semiconductor structures according to various disclosed embodiments of the present disclosure.

FIG. 33 is a schematic diagram comparing target structures of two semiconductor structures.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

As mentioned in the background section, the SALELE process is a common solution in back-end patterning. The process has two core values in patterning. The first value is the spacing between metal lines defined by two lithographies is determined by the thickness of the spacer during the process. The spacer is usually formed by an atomic layer deposition (ALD) process with very high uniformity. As such, the overlay of two lithographies does not cause a change of spacing between two adjacent metal lines. It also makes the spacing between metal lines very uniform and fixed, and opens a large process window for reliability tests such as time dependent dielectric breakdown (TDDB) and breakdown voltage (VBD). The second value is that the tip to tip of the metal lines defined by two lithographies may be formed very small by using cuts of patterning produced by other masks. Further, a cut corresponding to the first lithography and a cut corresponding to the second lithography may not interfere with each other. This is also called a self-aligned block process in the industry.

The above two advantages are the reason that SALELE not only balances the process difficulty at the back-end patterning, but also provides great design freedom. The SALELE process also has various similar solutions, such as that shown in CN111640668B and process solutions disclosed in US10991596B2.

In general, the minimum pitch created by immersion DUV (ArFi) in a single photolithography is about 80 nm. Thus, SALELE may use DUV equipment to achieve a minimum pitch of 38 nm to 40 nm, while more advanced chips require smaller pitches, such as 32 nm, 28 nm, 24 nm, etc.

With the traditional fin patterning, when a pitch reaches about 30 nm, the SAQP process may be used. Because SADP may only make a fin pattern with a minimum pitch of 38 nm, SADP needs to be repeated to become SAQP. The SAQP process may well meet the needs of fin patterning. Because fin patterns are relatively regular, the fin pitches in an area of a chip are generally fixed and regular, and the difference between areas is not very large. However, the SAQP solution has great limitations in the back-end process where metal lines have a high degree of freedom. For example, when metal patterns of SRAM are formed, metal lines formed by patterning are difficult to match patterns of the first metal layer of the traditional SRAM. Further, the width of metal lines formed by SAQP is relatively fixed, which also makes designs of other bypass circuits more difficult.

As such, currently for back-end patterning in semiconductor structures of the same area, it is difficult to achieve both smaller pitch and design freedom, meet more requirements of semiconductor processes, and improve design freedom in patterning processes correspondingly. The traditional SAQP process is difficult to remove redundant metal lines without adding a mask, which means that the SAQP process may often form the densest metal line arrangement. The spacing between densely packed metal lines is fixed and is determined by the second sidewall in the SAQP process. However, metal winding often needs to consider not only providing a smaller metal pitch, but also a smaller capacitance within the metal line layer. In the 2015 SPIE conference paper “Impact of a SADP flow on the design and process for N10/N7 Metal” doi: 10.1117/12.2085923, harms caused by redundant metal lines and methods of removing them in an SADP process are elaborated in detail. However, the paper primarily uses additional masks to remove excess metal lines, as shown in FIG. 33. A target structure with redundant metal lines removed is shown in part (a) of FIG. 33. However, in this paper, when only the cutting process is used, the redundant metal lines may only be retained in the final structure as shown in part (b) of FIG. 33.

In order to solve the above technical problems, embodiments of the present disclosure provide a method for forming semiconductor structures. The method includes providing a base, wherein the base includes a substrate and a target material layer on the substrate, a second core material layer and a first core material layer on the second core material layer are formed on the base, the base further includes a first area for forming first target structures and a second area for forming second target structures, the first target structures and the second target structures extend along a first direction, and a pitch of adjacent first target structures is less than or equal to a pitch of adjacent second target structures; patterning the first core material layer and forming separate first core layers in the first area, wherein the first core layers extend along the first direction and are arranged in parallel along the second direction, and the first direction is perpendicular to the second direction; forming first spacers covering sidewalls of the first core layers; removing the first core layers; forming a first protective layer on the second core material layer in the second area, wherein separate first protective layer openings extending along the first direction and arranged in parallel along the second direction are formed in the first protective layer; patterning the second core material layer with the first spacers and the first protective layer as a mask and forming second core layers; removing the first spacers and the first protective layer; forming second protective layers on the second core layers, wherein the second protective layers are separated in the second area; modifying the second core layers exposed in the second area with the second protective layers as a mask and forming third core layers having an etching selectivity ratio with the remaining second core layers; removing the second protective layers; forming second spacers covering sidewalls of the second core layers and the third core layers; removing the second core layers; patterning the target material layer with the second spacers and the third core layers as a mask and forming the first target structures in the first area and the second target structures in the second area.

In embodiments of the present disclosure, the first core layers are formed in the first area. The first spacers are formed to cover sidewalls of the first core layers. The first protective layer is formed on the second core material layer in the second area. The first protective layer is formed with the first protective layer openings that are separate, extend along the first direction, and are arranged in parallel along the second direction. The second core material layer is patterned with the first spacers and the first protective layer as a mask to form the second core layers. For the first area, the second spacers covering sidewalls of the second core layers are formed, and the target material layer is patterned with the second spacers as a mask. The above processes use SAQP. The SAQP process may form the first target structures with a smaller pitch. For the second area, portions of the second core layers in the second area are modified with the second protective layer as a mask. The portions of the second core layers are transformed into third core layers having an etching selectivity ratio with the second core layers. The second spacers covering sidewalls of the second core layers and the third core layers are formed. The target material layer is patterned with the second spacers and the third core layers as a mask. The above processes use SALELE that may form the second target structures with a larger pitch. Embodiments of the present disclosure may better integrate the SAQP process and the SALELE process, and form the first target structures with a smaller pitch and the second target structures with a larger pitch over the same base. It is conducive to meeting more semiconductor process requirements through process integration and improving the design freedom in patterning processes.

In order to make the above-mentioned objects, features, and advantages of the present disclosure more obvious and easier to understand, embodiments of the present disclosure are described in detail below in conjunction with the accompanying drawings.

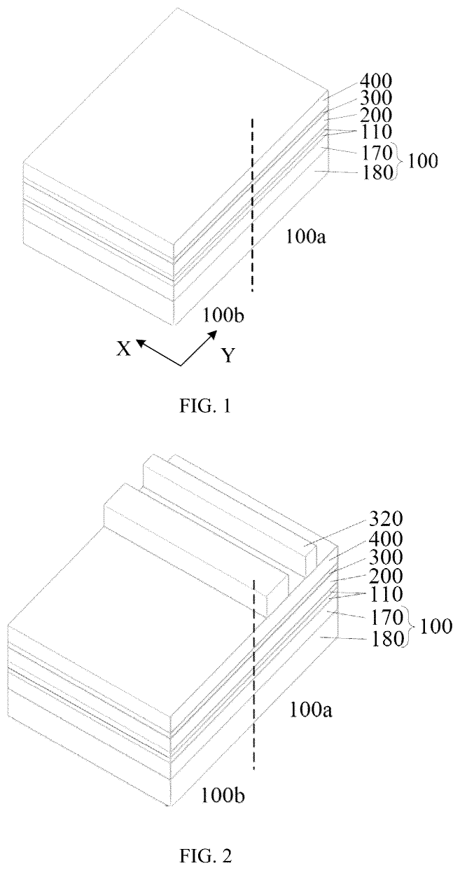

FIGS. 1 to 32 are schematic structural diagrams corresponding to steps of methods for forming semiconductor structures according to embodiments of the present disclosure.

Referring to FIG. 1, a base 100 is provided. The base 100 includes a substrate 180 and a target material layer 170 on the substrate 180. A second core material layer 200 and a first core material layer 400 on the second core material layer 200 are formed over the base 100. The base 100 includes a first area 100a for forming first target structures and a second area 100b for forming second target structures. Both the first target structure and second target structure extend along a first direction (i.e., the X direction in FIG. 1). The pitch of adjacent first target structures is smaller than or equal to the pitch of adjacent second target structures.

The base 100 provides a process operation basis for formation processes of semiconductor structures. Exemplarily, the semiconductor structures include metal interconnection lines, barrier layers, adhesion layers, cap layers, etc.

In some embodiments, the substrate 180 is a wafer on which transistors and part of connection lines are formed.

In some embodiments, the base 100 includes the first area 100a used for forming multiple first target structures and a second area 100b used for forming multiple second target structures. The pitch of adjacent first target structures is smaller than or equal to the pitch of adjacent second target structures.

In some embodiments, during formation processes of a semiconductor structure, it is necessary to form denser first target structures and sparser second target structures. For example, the pitch of adjacent first target structures is smaller than or equal to the pitch of adjacent second target structures. The SAQP process may be used to form denser target structures. However, it is hard to use SAQP to create sparser target structures. In addition, the pitch between target structures is relatively fixed and difficult to adjust freely according to layout needs. When the SALELE process is used, the pitch between target structures may be defined according to the layout. Further, the pitch is easy to adjust, and a self-aligned block process may be realized. However, it is difficult to use SALELE to form denser (e.g., a pitch smaller than 38 nm) target structures. In some embodiments, the SAQP process is used in the first area 100a, and the SALELE process is used in the second area 100b. As such, the base 100 including the first area 100a for forming the first target structures and the second area 100b for forming the second target structures indicates the following may be achieved in some embodiments: Fabricating the first target structures with smaller pitches that are difficult to make with the SALELE process and fabricating the second target structures with larger pitches that are difficult to make with the SAQP process and having more freedom in design over the same base 100 (e.g., a same wafer).

In some embodiments, the first area 100a includes a logic device area. The second area 100b includes a peripheral device area. The logic device area has denser patterns, and the peripheral device area has sparser patterns. Optionally, the logical device area includes device areas containing a central processing unit (CPU) and a graphics processing unit (GPU), and the peripheral device area includes device areas containing static random-access memory (SRAM), input and output (IO) devices, etc.

Optionally, the pitch of adjacent first target structures is 24 nm to 38 nm and the pitch of adjacent second target structures is 38 nm to 200 nm.

The minimum pitch refers to the sum of the minimum width of the first target structure and the minimum spacing between adjacent first target structures when the first target structures and the second target structures are subsequently formed.

Thus, the SAQP process may be used to form the first target structures, and the SALELE process may be used to form the second target structures. The first target structures with a pitch of 24 nm to 38 nm and the second target structures with a pitch of 38 nm to 200 nm may be formed over the same base 100.

In some embodiments, the thickness of gate oxide layers in the logic device area is smaller than the thickness of gate oxide layers in the peripheral device area. Generally, the operating voltage of CPU or GPU transistors is lower than that of transistors in the IO device area. For example, the operating voltage of CPU transistors may be 0.75 V, while the operating voltage of transistors in an IO device area may be 1.2 V or even 1.8 V. Usually, in order to maintain the reliability and electrical performance of transistors in an IO device area, the gate oxide layer of transistors in the IO device area may be thicker than that in a logic device area. The thickness difference mainly comes from the thickness of a high-K (HK) dielectric layer of a high-K metal gate (HKMG) and the thickness of an interface layer (e.g., a silicon oxide layer) between transistor channels. Optionally, the interface layer in a gate oxide layer of the logic device area is thinner than that in the IO device area, and the HK dielectric layers over the interface layer in the two areas have the same thickness. The interface layer and HK dielectric layer together form a gate dielectric layer of a corresponding transistor. Thus, the thickness of a gate oxide layer in the logic device area is smaller than that in the peripheral device area.

The target material layer 170 is used to provide a process platform for forming the first target structures and the second target structures.

In some embodiments, in the step of providing the base 100, the target material layer 170 is a dielectric layer, the first target structures are first trenches, and the second target structures are second trenches.

The first trenches and second trenches provide spatial locations for subsequent processes. The target material layer 170 is a dielectric layer used to isolate structures formed in the first trenches and second trenches.

In some embodiments, materials of the dielectric layer include one or more of silicon oxide, silicon nitride, silicon oxynitride, silicon oxycarbide, silicon carbonitride, silicon oxynitride, a low-K (LK) material (e.g., a material of an LK dielectric layer), and an ultralow-K (ULK) material (e.g., a material of an ULK dielectric layer).

In some embodiments, in the step of providing the base 100, a mask material layer 110 is formed between the target material layer 170 and the second core material layer 200.

The mask material layer 110 is used to form a second pattern transfer layer.

In some embodiments, the mask material layer 110 has a stacked structure, including a titanium nitride layer and a silicon oxide layer over the titanium nitride layer.

The second core material layer 200 is used to form second core layers, third core layers, and fourth core layers.

In some embodiments, after the second core layers and the fourth core layers are formed, the second core layers and the fourth core layers will be removed later. Therefore, the material of the second core material layer 200 is a material that is easy to remove, thereby reducing the difficulty of removing the second core layers and the fourth core layers and reducing the damage to other layers below the second core material layer 200. Optionally, the material of the second core material layer 200 includes one or more of amorphous silicon (a-Si), polycrystalline silicon, single crystal silicon, silicon oxide, advanced patterning film (APF) material, spin on carbon (SOC), and silicon carbide. Exemplarily, the material of the second core material layer 200 may be a-Si.

In some embodiments, in the step of providing the base 100, an etching stop layer 300 is formed between the first core material layer 400 and the second core material layer 200.

The etching stop layer 300 is used to form the first pattern transfer layer. The etching stop layer 300 is also used as an etching stop layer when the first core material layer 400 is patterned, and protects the second core material layer 200 to prevent the second core material layer 200 from being damaged.

In some embodiments, the material of the etching stop layer 300 includes one or more of silicon oxide, silicon nitride, silicon oxynitride, silicon carbide, titanium, titanium oxide, titanium nitride, tantalum, tantalum oxide, tantalum nitride, boron nitride, copper nitride, aluminum nitride, and tungsten nitride. Exemplarily, the material of the etching stop layer 300 may be silicon oxide.

The first core material layer 400 is used to form first core layers later.

In some embodiments, after the first core layers are formed, the first core layers will be removed later. Therefore, the material of the first core material layer 400 is a material that is easy to remove, thereby reducing the difficulty of removing the first core layers and reducing the damage to other layers below the first core material layer 400. Optionally, the material of the first core material layer 400 includes one or more of a-Si, polycrystalline silicon, single crystal silicon, silicon oxide, APF material, SOC, and silicon carbide. Exemplarily, the material of the first core material layer 400 is a-Si.

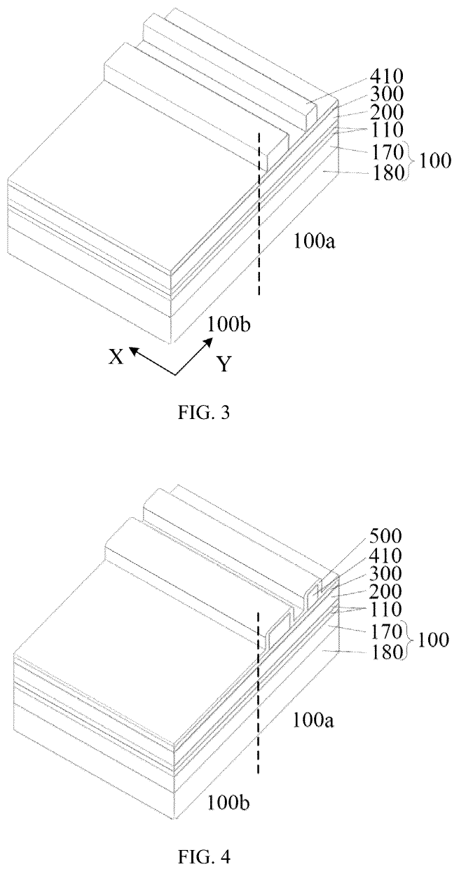

Referring to FIGS. 2 and 3, the first core material layer 400 is patterned and first core layers 410 are formed that are separate in the first area 100a, extend along the first direction, and are arranged in parallel along the second direction. The first direction is perpendicular to the second direction.

The first core layers 410 are used to provide support for the formation of first spacers.

In some embodiments, the first core material layer 400 is patterned by a dry etching process. The dry etching of a-Si is easier to stop on silicon oxide material used as the first etching stop layer 300 in some embodiments.

The dry etching process is an etching process with anisotropic etching characteristics. Its longitudinal etching rate is much greater than the lateral etching rate. Therefore, by selecting the dry etching process, it is beneficial to improve the accuracy of pattern transfer. At the same time, dry etching is more directional, which is beneficial to improve the sidewall morphology quality and dimensional accuracy of the first core layers 410.

In some embodiments, the material of the first core layers 410 is a-Si, so that in the process of patterning the first core material layer 400, the damage to the etch stop layer 300 is reduced. After the first core material layer 400 is patterned, the etch stop layer 300 still maintains a good size and morphology accuracy. Thus, the material of the first core layers 410 is selected to be easy to remove, and subsequent processes of removing the first core layers 410 have little effect on the etch stop layer 300.

In some embodiments, the size and pitch of the first core layers 410 are set according to the size and pitch of the first target structures subsequently formed in the first area 100a.

Referring to FIG. 2, the step of patterning the first core material layer 400 includes forming separate first mask layers 320 on the first core material layer 400 in the first area 100a.

The first mask layers 320 are used as an etching mask for patterning the first core material layer 400.

In some embodiments, the first mask layer 320 includes an SOC layer, a silicon-containing antireflective coating (Si-ARC) on the SOC, and a photoresist layer on the Si-ARC. The first mask layers 320 may be formed by photolithography and several etching steps.

Referring to FIG. 3, the first core material layer 400 is patterned through the first mask layers 320 to form the first core layers 410 that are separate in the first area 100a.

In some embodiments, after forming the first core layers 410, the method further includes removing the first mask layers 320.

The first mask layers 320 are removed to prepare for formation of first spacers.

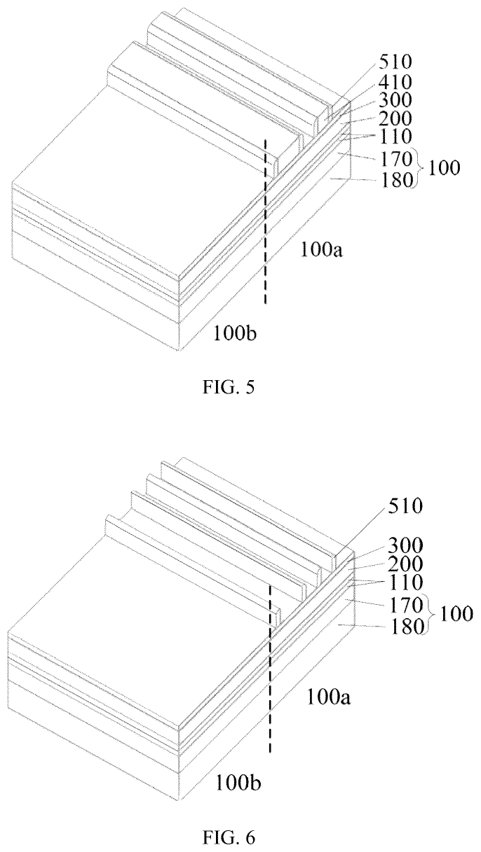

Referring to FIG. 4 and FIG. 5, first spacers 510 covering sidewalls of the first core layers 410 are formed.

The first spacers 510 are used as an etching mask for patterning the second core material layer 200.

In some embodiments, the material of the first spacers 510 includes one or more of titanium oxide, titanium nitride, silicon oxide, silicon nitride, silicon oxynitride and silicon carbide.

Titanium oxide, titanium nitride, silicon oxide, silicon nitride, silicon oxynitride, and silicon carbide may form a good etching selectivity with the first core layers 410, thereby reducing damage to the first spacers 510 in steps of removing the first core layers 410.

Optionally, referring to FIG. 4, the step of forming the first spacers 510 covering sidewalls of the first core layers 410 includes forming a first spacer material layer 500 covering sidewalls and tops of the first core layers 410 and the top of the second core material layer 200.

Optionally, the first spacer material layer 500 covers sidewalls and tops of the first core layers 410 and the top of the etching stop layer 300.

The first spacer material layer 500 is used to directly form the first spacers 510, and optionally, the material of the first spacer material layer 500 includes one or more of titanium oxide, titanium nitride, silicon oxide, silicon nitride, silicon oxynitride, and silicon carbide.

In some embodiments, ALD is used to form the first spacer material layer 500 covering the sidewalls and tops of the first core layers 410 and the top of the etching stop layer 300.

The first spacer material layer 500 formed by ALD has good thickness uniformity and good step coverage, so that the first spacer material layer 500 may conformally cover the sidewalls and tops of the first core layers 410 and the top of the second core material layer 200.

Referring to FIG. 5, the first spacer material layer 500 on the tops of the first core layers 410 and above the second core material layer 200 is removed, and the first spacer material layer 500 on the sidewalls of the first core layers 410 is retained as the first spacers 510.

Optionally, the first spacer material layer 500 on the tops of the first core layers 410 and the top of the etch stop layer 300 is removed.

In some embodiments, a dry etching process is used to remove the first spacer material layer 500 on the tops of the first core layers 410 and the top of the etch stop layer 300.

The dry etching process is an anisotropic etching process. Therefore, by selecting the dry etching process, it is beneficial to reduce the damage to the first core layers 410 and the etching stop layer 300. At the same time, dry etching is more directional, which is beneficial to improve the sidewall morphology quality and dimensional accuracy of the first spacers 510.

Referring to FIG. 6, the first core layers 410 are removed.

The first core layers 410 are removed to prepare for patterning the etching stop layer 300 and the second core material layer 200 using the first spacers 510 as a mask.

In some embodiments, the first core layers 410 are removed by a wet etching process.

The wet etching process has the characteristic of isotropic etching, which is conducive to clean removal of the first core layers 410. Moreover, the cost of the wet etching process is relatively low, and the operation steps are simple. It may also achieve a large etching selectivity ratio, which is conducive to reducing the damage to the first spacers 510 during removal of the first core layers 410.

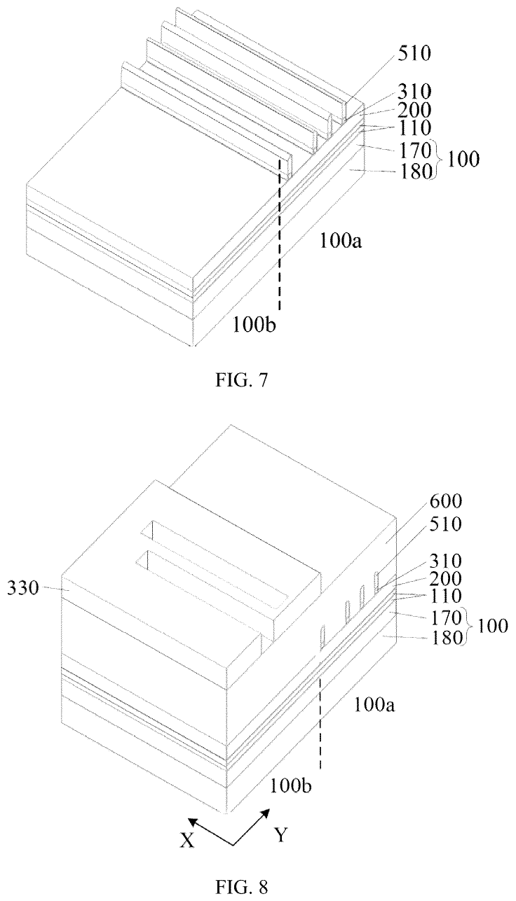

Referring to FIG. 7, before the first protective layer is formed on the second core material layer 200 in the second area 100b, the method further includes using the first spacers 510 as a mask to pattern the etching stop layer 300 and forming a first pattern transfer layer 310.

The first pattern transfer layer 310 is used as an etching mask for patterning the second core material layer 200 in the first area 100a.

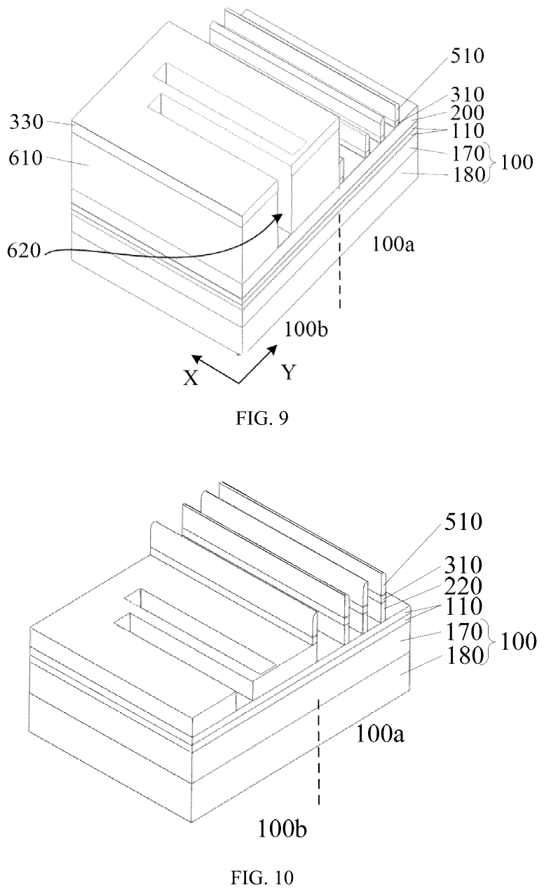

With reference to FIGS. 8 and 9, a first protective layer 610 is formed on the second core material layer 200 in the second area 100b. First protective layer openings 620 are formed that are separate in the first protective layer 610, extend along the first direction, and are arranged in parallel along the second direction.

The first protective layer 610 is used as an etching mask for patterning the second core material layer 200.

In some embodiments, the first protective layer 610 is patterned from a planarization layer. The material of the first protective layer 610 includes SOC material or SOC with a remaining portion of a second mask layer 330. Whether the second mask layer 330 remains or not is related to a process selection and does not affect the subsequent steps. SOC is formed by a spin coating process, and the process cost is relatively low. By using SOC, it is beneficial to improve the flatness of the top surface of the planarization layer, thereby providing a good interface for formation of the first protective layer 610.

Referring to FIG. 8, the step of forming the first protective layer 610 on the second core material layer 200 in the second area 100b includes forming a first protective material layer 600 covering the second core material layer 200 and sidewalls of the first spacers 510 and the first pattern transfer layer 310.

In some embodiments, the second mask layer 330 is formed on the first protective material layer 600. The second mask layer 330 exposes the first protective material layer 600 in the first area 100a and is on the first protective material layer 600 in the second area 100b.

The second mask layer 330 is used to pattern the first protective material layer 600.

In some embodiments, the second mask layer 330 includes Si-ARC and a photoresist layer on the Si-ARC.

In some embodiments, a photomask and related photolithography and etching processes are used to pattern the second mask layer 330 in the first area 100a and the second area 100b. The first protective material layer 600 is patterned with the second mask layer 330 to form a first protective layer 610. Then the first protective layer 610 in the second area 100b and the first spacers 510 in the first area are used as a mask to pattern the second core material layer 200 to form second core layers 220. Since the process of forming the second mask layer 330 by using a photomask is highly flexible, and the patterns are diverse, the design is relatively free within the range allowed by a single photolithography. That is, the size and pitch of the first protective layer openings 620 in the first protective layer 610 are relatively free, as long as they meet the single DUV photolithography limit and the pitch is greater than about 76 nm. Accordingly, the size and pitch design of trenches surrounded by the second spacer material layer supported by sidewalls of the second core layers 220 are relatively free. Therefore, second target structures with a larger pitch may be obtained in the second area 100b, and the freedom of patterning design is improved.

Referring to FIG. 9, the first protective material layer 600 in the second area 100b is patterned. The first protective material layer 600 in the first area 100a is removed. Separate portions of the first protective material layer 600 in the second area 100b are formed as the first protective layer 610.

Optionally, the first protective material layer 600 is patterned using the second mask layer 330 as an etching mask.

In some embodiments, after forming separate portions of the first protective material layer 600 in the second area 100b as the first protective layer 610, the method further includes removing the second mask layer 330.

Referring to FIG. 10, the second core material layer 200 is patterned with the first spacers 510 and the first protective layer 610 as a mask to form second core layers 220.

Optionally, the second core layers 220 formed in the first area 100a present a morphology extending along the first direction and arranged in parallel along the second direction. The morphology of the second core layers 220 is similar to that of the first spacers 510. The second core layers 220 formed in the second area 100b have an opening morphology extending along the first direction and arranged in parallel along the second direction. The opening morphology of the second core layers 220 is similar to that of the first protective layer openings 620.

The second core layers 220 are used to provide support for formation of the second spacers.

In some embodiments, the material of the second core layers 220 is a-Si.

In some embodiments, in the step of patterning the second core material layer 200 with the first spacers 510 and the first protective layer 610 as a mask and forming the second core layers 220, the second core material layer 200 in the first area 100a is patterned with the first pattern transfer layer 310 as a mask to form separate second core layers 220 in the first area 100a.

The second core material layer 200 in the first area 100a is patterned with the first pattern transfer layer 310 as a mask to form separate second core layers 220 in the first area 100a. It is conducive to improving the pattern transfer accuracy, thereby helping to improve the pattern size accuracy of the second core layers 220.

The second core layers 220 in the first area 100a are obtained from transfer of the first spacers 510. The pitch of the first spacers 510 has been halved based on the pitch of the first mask layer 320. This is also an SADP process, which has achieved a halving from the single DUV lithography etching limit of about 80 nm to about 40nm. This prepares for formation of the second spacers on sidewalls of the second core layers to achieve another halving of the second spacer pitch compared with the first spacers 510. This is also the characteristic of the SAQP process and the reason why SAQP may form a pattern with a pitch of about 24 nm.

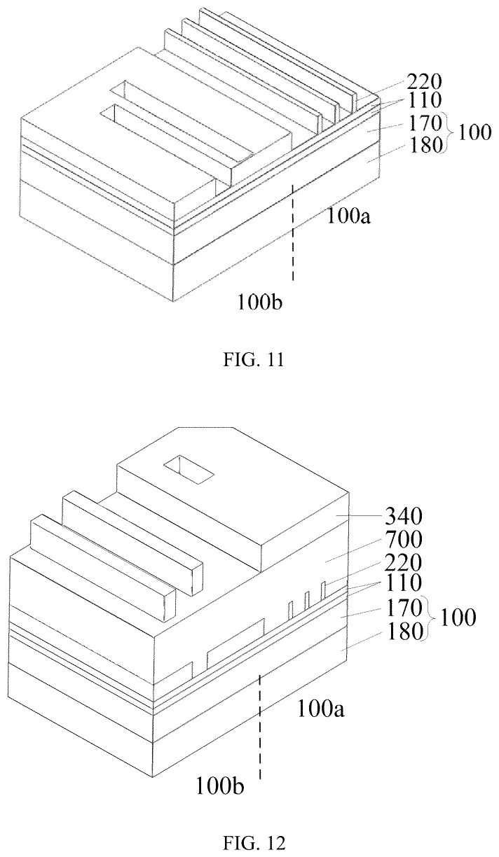

Referring to FIGS. 10 and 11, the first spacers 510 and the first protective layer 610 are removed.

Removal of the first spacers 510 and the first protective layer 610 prepares for formation of second protective layers.

In some embodiments, an etching process is used to remove the first protective layer 610.

In some embodiments, either an isotropic or anisotropic etching process may be used. It is only necessary to ensure the etching selectivity of the etching process so that the etching process has a relatively large etching selectivity for the first protective layer 610 and the second core layers 220, thereby reducing damage to the second core layers 220 during the removal of the first protective layer 610.

In some embodiments, after forming the second core layers 220, the method further includes removing the first pattern transfer layer 310.

The first pattern transfer layer 310 is removed to prepare for formation of the second spacers.

In some embodiments, a wet etching process is used to remove the first spacers 510 and the first pattern transfer layer 310.

The wet etching process has the characteristic of isotropic etching, which is conducive to completely removing the first spacers 510 and the first pattern transfer layer 310. Moreover, the cost of the wet etching process is relatively low, and the operation steps are simple. It may also achieve a large etching selectivity ratio, which is conducive to reducing damage to the second core layers 220 during removal of the first spacers 510 and the first pattern transfer layer 310.

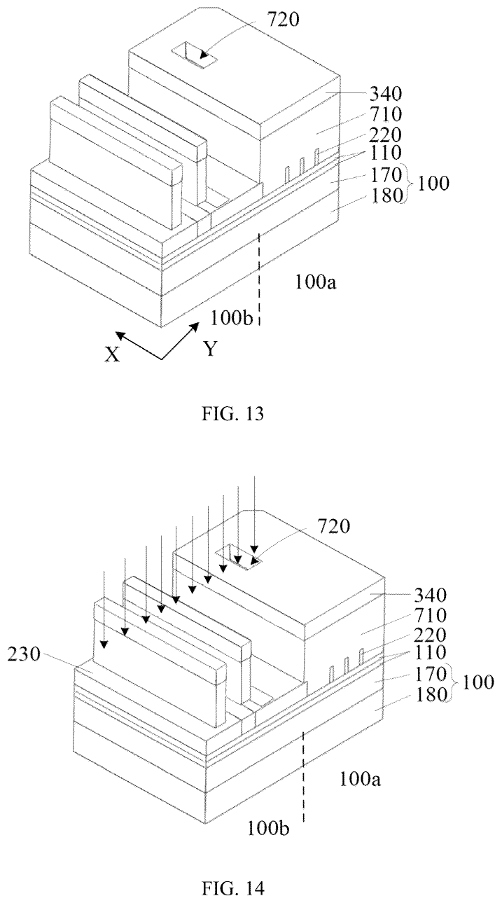

Referring to FIGS. 12 and 13, second protective layers 710 are formed on the second core layers 220. The second protective layers 710 in the second area 100b are separately arranged.

The second protective layer 710 in the first area 100a is used to cover the first area 100a and protect the second core layers 220 in the first area 100a from damage. The second protective layers 710 in the second area 100b are used as an implantation mask for ion implantation in the second core layers 220 in the second area 100b.

In some embodiments, in the step of forming the second protective layers 710 on the second core layers 220, second protective layer openings 720 exposing the second core layers 220 are formed in the second protective layer 710 in the first area 100a. The second protective layer openings 720 extend along the first direction.

The second protective layer openings 720 expose part of the second core layers 220. The exposed second core layers 220 later may be modified.

Optionally, in the step of forming the second protective layer on the second core layers, the second protective layer covers the second core layers in the first area. The second protective layer does not form second protective layer openings in the first area but completely covers the second core layers in the first area.

In some embodiments, the material of the second protective layer 710 includes SOC material.

Optionally, referring to FIG. 12, the step of forming the separate second protective layers 710 on the second core layers 220 in the second area 100b and covering the second core layers 220 in the first area 100a includes forming a second protective material layer 700 covering the second core layers 220.

The second protective material layer 700 is used to form the second protective layers 710.

In some embodiments, the second protective material layer 700 is a planarization layer, and the material of the second protective material layer 700 includes a SOC material. The SOC is formed by a spin coating process, and the process cost is relatively low. Moreover, by adopting the SOC, it is beneficial to improve the flatness of the top surface of the second protective material layer 700, thereby providing a good interface for the formation of the second protective layer.

In some embodiments, third mask layers 340 are formed on the second protective material layer 700. The third mask layers 340 cover the second protective material layer 700 in the first area 100a and are separately arranged on the second protective material layer 700 in the second area 100b. Mask openings extending along the first direction are formed in the third mask layer 340 in the first area 100a.

The third mask layers 340 are used to pattern the second protective material layer 700.

In some embodiments, the third mask layers 340 include Si-ARC and a photoresist layer on the Si-ARC.

Referring to FIG. 13, the second protective material layer 700 in the second area 100b is patterned. Separate second protective layers 710 are formed on the second core layers 220 in the second area 100b. The second protective layers 710 covering the second core layers 220 and having second protective layer openings 720 exposing the second core layers 220 are formed in the first area 100a.

Optionally, the second protective material layer 700 is patterned using the third mask layers 340 as an etching mask.

Referring to FIG. 14, the second core layers 220 exposed in the second area 100b are modified using the second protective layers 710 as a mask. The third core layers 230 are formed that have an etching selectivity ratio with the remaining second core layers 220.

The second core layers 220 exposed in the second area 100b are modified to obtain the third core layers 230 having an etching selectivity ratio with the second core layers 220. The remaining second core layers 220 may be easily removed later. Further, in a process of removing the remaining second core layers 220, the damage to the third core layers 230 is reduced. The third core layers 230 are used to prepare for patterning the target material layer 170 in the second area 100b.

In some embodiments, in the step of modifying the second core layers 220 exposed in the second area 100b using the second protective layers 710 as a mask, the second core layers 220 exposed by the second protective layer openings 720 in the first area 100a are also modified. The third core layers 230 in the first area 100a are formed. In a subsequent process of removing the second core layers 220, the third core layers 230 in the first area 100a are retained.

In some embodiments, the third core layers 230 are also formed in the first area 100a. When the target material layer 170 is patterned using the second spacers and the third core layers 230 as a mask, portions of the target material layer 170 corresponding to the third core layers 230 in the first area 100a are retained to block formation of the first target structures at certain locations. Thus, some of the redundant first target structures in the first area 100a made by SAQP may be removed without adding a mask and process steps.

Optionally, in the step of modifying the second core layers 220 exposed in the second area 100b using the second protective layers 710 as a mask, the second core layers 220 exposed in the second area 100b are ion implanted using the second protective layers 710 as a mask, forming the third core layers 230 having an etching selectivity ratio with the remaining second core layers 220.

The ion implantation process has the characteristics of uniform large-area ion implantation, more accurate control of ion doping depth and high repeatability. The third core layers 230 are obtained by ion implantation, which is conducive to accurately controlling the doping concentration and distribution of the third core layers 230 and the penetration depth in the second core layers 220. The ion distribution in the third core layers 230 is relatively uniform.

In some embodiments, in the step of modifying the second core layers 220 exposed in the second area 100b using the second protective layers 710 as a mask, the second core layers 220 exposed in the second area 100b are ion implanted using the second protective layers 710 as a mask, forming the third core layers 230 having an etching selectivity ratio with the remaining second core layers 220.

In some embodiments, in the step of performing ion implantation in the second core layers 220 exposed in the second area 100b using the second protective layers 710 as a mask, the ions implanted in the ion implantation process include one or more of boron, phosphorus, arsenic, boron chloride, boron dichloride, and carbon.

In some embodiments, the material of the second core layers 220 is a-Si. By implanting one or more ions of boron, phosphorus, arsenic, boron chloride, boron dichloride and carbon into the second core layers 220, a-Si may be converted into a material having a higher etching selectivity ratio with a-Si, thereby obtaining the third core layers 230 having a higher etching selectivity ratio with the second core layers 220.

In some embodiments, the material of the second core layers 220 is a-Si, and the material of the third core layers 230 is a-Si doped with boron, phosphorus, or arsenic.

In some embodiments, a photomask and a photolithography process are used to pattern the third mask layers 340 in the second area 100b and the first area 100a. The second protective material layer 700 is patterned with the third mask layers 340 to form the second protective layers 710. The second core layers 220 are ion implanted with the second protective layers 710 as a mask to form the third core layers 230 having an etching selectivity ratio with the second core layers 220. The process flexibility of forming the second protective layers 710 is high. The width and pitch of the second protective layers 710 are easy to adjust, which makes the width and pitch of the remaining second core layers 220 in the second area 100b easy to adjust accordingly. Thus, some second target structures with a larger pitch may be obtained in the second area 100b, and the degree of freedom of pattern design is improved.

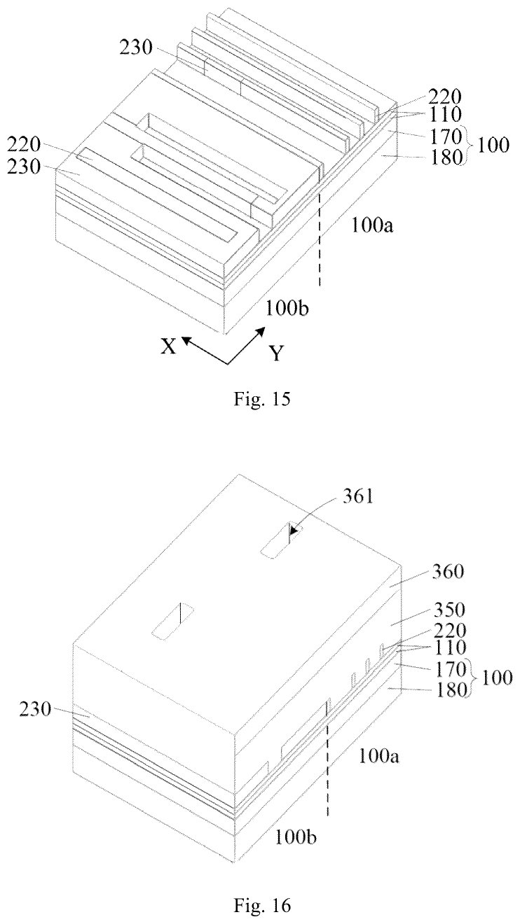

Optionally, in the step of modifying the second core layers 220 exposed in the second area 100b using the second protective layers 710 as a mask, the size of the remaining second core layers 220 along the second direction (the Y direction in FIG. 15) is 35 nm to 200 nm, and the pitch along the second direction is 76 nm to 200 nm. The size of the third core layers 230 along the second direction is 35 nm to 200 nm, and the pitch is 76 nm to 200 nm.

Referring to FIG. 15, the second protective layers 710 and the third mask layers 340 are removed.

The second protective layers 710 are removed to prepare for removal of the second core layers 220.

In some embodiments, the second protective layers 710 are removed by dry etching.

In some embodiments, either isotropic or anisotropic etching process may be used. It is only necessary to ensure the etching selectivity of the etching process so that the etching selectivity of the etching process for the second protective layers 710 and the second core layers 220, and for the second protective layers 710 and the third core layers 230 is relatively large, thereby reducing the damage to the second core layers 220 and the third core layers 230 during the removal of the second protective layers 710.

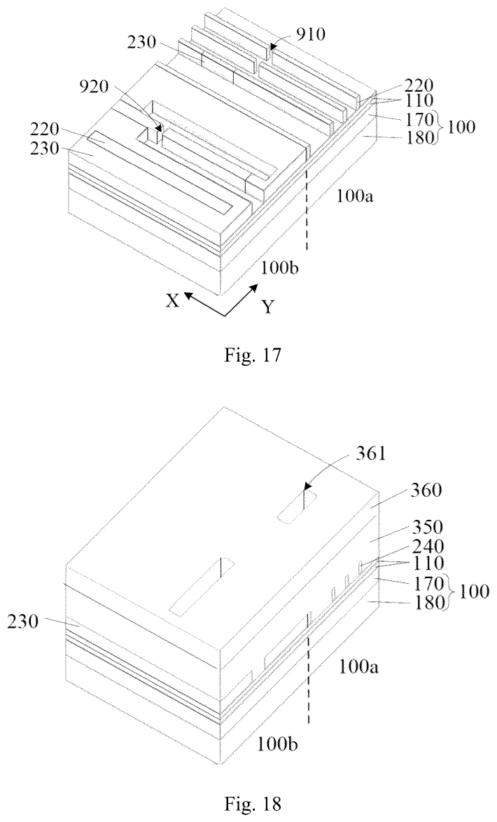

Referring to FIGS. 16 and 17, after removing the second protective layers 710, and before forming second spacers covering sidewalls of the second core layers 220 and the third core layers 230, the method further includes patterning part of the second core layers 220 in the first area 100a, and part of the second core layers 220 and the third core layers 230 in the second area 100b, forming first separation openings 910 that cut off the second core layers 220 in the first area 100a in the first direction, and second separation openings 920 that cut off part of the second core layers 220 in the second area 100b in the first direction.

The first separation openings 910 are used to form first separation structures, and the second separation openings 920 are used to form second separation structures.

In some embodiments, the steps of patterning portions of the second core layers 220 in the first area 100a, and portions of the second core layers 220 and the third core layers 230 in the second area 100b, and forming the first separation openings 910 that cut off the second core layers 220 in the first area 100a in the first direction, and the second separation openings 920 that cut off the second core layers 220 in the second area 100b in the first direction include the following: Referring to FIG. 16, a third protective layer 350 covering the second core layers 220 and the third core layers 230 is formed, a fourth mask layer 360 is formed on the third protective layer 350, and fourth mask layer openings 361 are formed in the fourth mask layer 360 that cross the second core layers 220 in the first area 100a and the second area 100b along the second direction. Referring to FIG. 17, the second core layers 220 are patterned through the third protective layer 350 and the fourth mask layer openings 361, the first separation openings 910 cutting off the second core layers 220 in the first area 100a along the first direction are formed, and the second separation openings 920 cutting off the second core layers 220 in the second area 100b along the first direction are formed.

In some embodiments, the third protective layer 350 is a planarization layer. The material of the third protective layer 350 includes an SOC material. The SOC is formed by a spin coating process, and the process cost is low. Moreover, by using the SOC, it is beneficial to improve the top surface flatness of the third protective layer 350, thereby providing a good interface for formation of the fourth mask layer 360.

The fourth mask layer 360 is used to pattern the second core layers 220 and the fourth core layers 240 through the third protective layer 350.

In some embodiments, the fourth mask layer 360 includes Si-ARC and a photoresist layer on the Si-ARC.

Referring to FIG. 17, after forming the first separation openings 910 that cut off the second core layers 220 in the first area 100a in the first direction and the second separation openings 920 that cut off the second core layers 220 in the second area 100b in the first direction, the method further includes removing the third protective layer 350 and the fourth mask layer 360.

Optionally, based on actual process requirements, the steps related to FIGS. 16 and 17 may be repeated to form multiple first separation openings 910 and second separation openings 920 at some target positions.

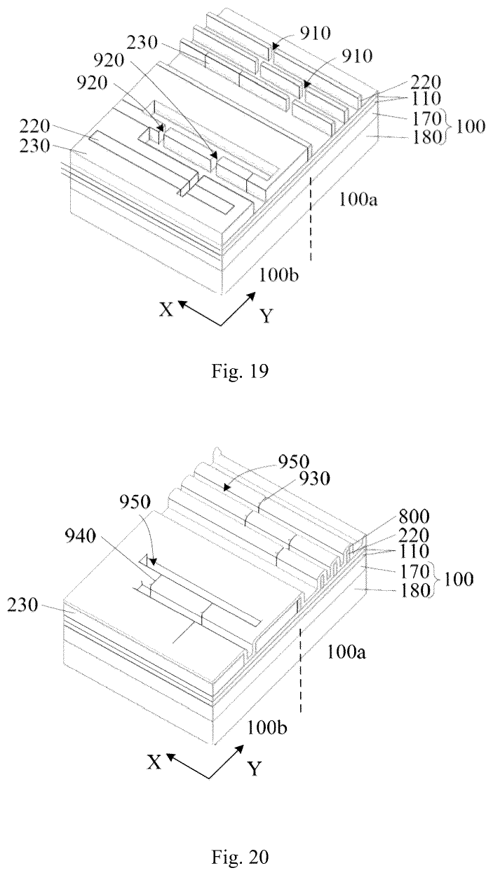

In some embodiments, the steps of forming the first separation openings 910 and the second separation openings 920 are performed twice, as shown in FIGS. 18 and 19. The third protective layer 350 covering the second core layers 220 and the third core layers 230 is formed. On the third protective layer 350, the fourth mask layer 360 is fabricated and formed with the fourth mask layer openings 361 that cross the second core layers 220 in the first area 100a and the second area 100b along the second direction. The second core layers 220 are patterned through the third protective layer 350 and the fourth mask layer openings 361. The first separation openings 910 cutting off the second core layers 220 in the first area 100a in the first direction and the second separation openings 920 cutting off the second core layers 220 in the second area 100b in the first direction are formed.

Referring to FIGS. 20-26, second spacers 810 are formed to cover sidewalls of the second core layers 220 and the third core layers 230.

The second spacers 810 are used as a partial etching mask for patterning the target material layer 170 in the first area 100a and the second area 100b.

In some embodiments, the material of the second spacers 810 includes one or more of titanium oxide, titanium nitride, silicon oxide, silicon nitride, silicon oxynitride, and silicon carbide.

Titanium oxide, titanium nitride, silicon oxide, silicon nitride, silicon oxynitride, and silicon carbide may form a good etching selectivity ratio with the second core layers 220 and the third core layers 230, thereby reducing the damage to the second spacers 810 in a subsequent step of removing the second core layers 220.

In some embodiments, in the step of forming the second spacers 810 covering sidewalls of the second core layers 220 and the third core layers 230, the second spacers 810 also covers sidewalls of the first separation openings 910 and sidewalls of the second separation openings 920. The double thickness of the second spacer 810 is smaller than the size of the first separation opening 910 and the second separation opening 920 along the first direction.

Therefore, second spacers 810 on opposite sidewalls of the first separation opening 910 are in contact to form first separation structures 930, and second spacers 810 on opposite sidewalls of the second separation opening 920 are in contact to form second separation structures 940.

The first separation structures 930 and the second separation structures 940 are used to transfer a pattern to the target material layer 170, so that separation between the first target structures and between the second target structures may be directly formed in the target material layer 170. After the target material layer 170 is patterned, some first target structures to be cut and some second target structures to be cut are directly cut off when the first target structures and the second target structures are formed in the target material layer 170.

Optionally, referring to FIG. 20, the step of forming the second spacers 810 covering sidewalls of the second core layers 220 and the third core layers 230 includes forming a second spacer material layer 800 covering the sidewalls and tops of the second core layers 220 and the third core layers 230, and the top of the base 100.

The second spacer material layer 800 is used to directly form the second spacers 810. Optionally, the material of the second spacer material layer 800 includes one or more of titanium oxide, titanium nitride, silicon oxide, silicon nitride, silicon oxynitride, and silicon carbide.

In some embodiments, ALD is used to form the second spacer material layer 800 covering the sidewalls and tops of the second core layers 220 and the third core layers 230, as well as the top of the base 100.

The second spacer material layer 800 formed by ALD has good thickness uniformity and good step coverage, so that the second spacer material layer 800 may conformally cover the sidewalls and tops of the second core layers 220 and the third core layers 230, as well as the top of the base 100.

In some embodiments, in the step of forming the second spacer material layer 800 covering the sidewalls and tops of the second core layers 220, the third core layers 230, and the fourth core layers 240, and the top of the base 100, the second spacer material layer 800 also fills the first separation openings 910 and the second separation openings 920.

The second spacer material layer 800 covering the sidewalls of the second core layers 220 and the third core layers 230 forms the second spacers 810. The second spacer material layer 800 filling the first separation openings 910 forms the first separation structures 930. The second spacer material layer 800 filling the second separation openings 920 forms the second separation structures 940.

In some embodiments, in a step of forming the second spacer material layer 800 covering the sidewalls and tops of the second core layers 220 and the third core layers 230 and the top of the base 100, portions of the second spacer material layer 800 on the opposite sidewalls surround and form trenches 950.

The first separation structures 930 only separate the first target structures corresponding to (directly below) the second core layers 220 in the first area 100a, but do not separate the trenches 950 formed by the second spacers 810 of the second core layers 220 in the first area 100a, and do not separate the first target structures corresponding to the trenches 950. This is also a special feature of the self-aligned block (SAB) technology mentioned in the background technology. Similarly, the second separation structure 940 only separate the second target structure corresponding to the second core layers 220 in the second area 100b, but do not separate the second target structures corresponding to the trenches 950 surrounded by the second spacer material layer 800 on sidewalls of the third core layers 230 and the second core layers 220 in the second area 100b.

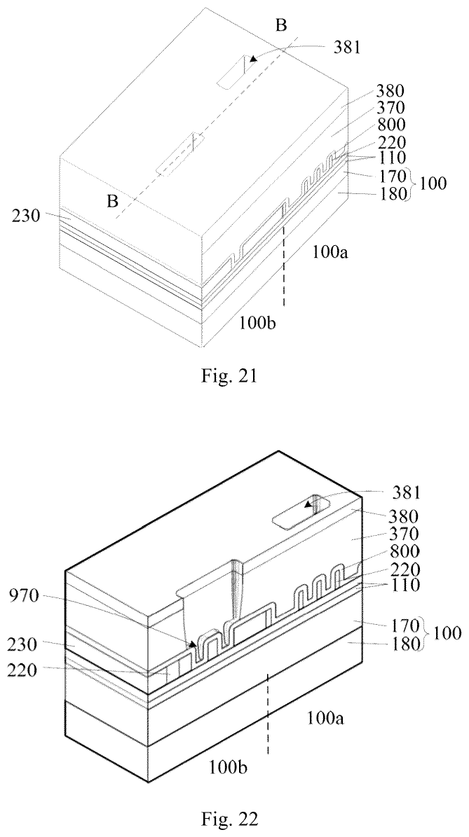

Referring to FIGS. 21-25, after forming the second spacers 810 covering the sidewalls of the second core layers 220 and the third core layers 230, and before removing the second spacer material layer 800 on the tops of the second core layers 220, the third core layers 230, and the base 100, the method further includes forming third separation structures 960 extending along the second direction and contacting the second spacers 810 in the trenches 950 in the first area 100a and the second area 100b. The third separation structures 960 separate the trenches 950 in the first direction.

The third separation structures 960 are used to transfer a pattern to the target material layer 170. As such, separations of the first target structures and separations of the second target structures corresponding to the trenches 950 in the first area 100a and the second area 100b may be directly formed in the target material layer 170. After the target material layer 170 is patterned, the first target structures to be cut (or separated) and the second target structures to be cut (or separated) are directly cut off (or separated) when the first target structures and the second target structures are formed in the target material layer 170.

Optionally, the third separation structures 960 only separate the first target structures corresponding to (directly below) the trenches 950 in the first area 100a, and do not separate first target structures corresponding to the second core layers 220 in the first area 100a. This is also the special feature of the SAB technology mentioned in the background technology. Similarly, the third separation structures 960 only separate the second target structures corresponding to the trenches 950 in the second area 100b, but do not separate second target structures corresponding to the second core layers 220 in the second area 100b.

Optionally, in the first area 100a, separations transferred from the third separation structures 960 to the target material layer 170 and separations transferred from the first separation structures 930 to the target material layer 170 are separations of adjacent first target structures. In the second area 100b, separations transferred from the third separation structures 960 to the target material layer 170 and separations transferred from the second separation structures 940 to the target material layer 170 are separations of adjacent second target structures. The first separation structures 930, second separation structures 940, and third separation structures 960 may be pre-formed. Thus, adjacent first target structures or adjacent second target structures may be simultaneously separated in the target material layer 170, providing a better method for forming separations with a smaller pitch.

Referring to FIGS. 21 and 22, FIG. 22 is a cross-sectional view of FIG. 21 along the BB direction. In some embodiments, steps of forming the third separation structures 960 extending along the second direction and contacting the second spacers 810 in the trenches 950 in the first area 100a and the second area 100b include: Forming a fourth protective layer 370 covering the second spacer material layer 800 and filling the trenches 950, forming a fifth mask layer 380 on the fourth protective layer 370, forming fifth mask layer openings 381 across the trenches 950 along the second direction in the fifth mask layer 380, patterning the fourth protective layer 370 through the fifth mask layer openings 381, removing the fourth protective layer 370 at corresponding positions of the fifth mask layer openings 381 in the trenches 950, and forming third separation openings 970.

In some embodiments, the fourth protective layer 370 is a planarization layer, and the material of the fourth protective layer 370 includes an SOC material. The SOC is formed by a spin coating process, and the process cost is low. Moreover, by using the SOC, it is beneficial to improve the flatness of the top surface of the fourth protective layer 370, thereby providing a good interface for formation of the fifth mask layer 380.

The fifth mask layer 380 is used to pattern the fourth protective layer 370 to form the third separation openings 970.

In some embodiments, the fifth mask layer 380 includes Si-ARC and a photoresist layer on the Si-ARC.

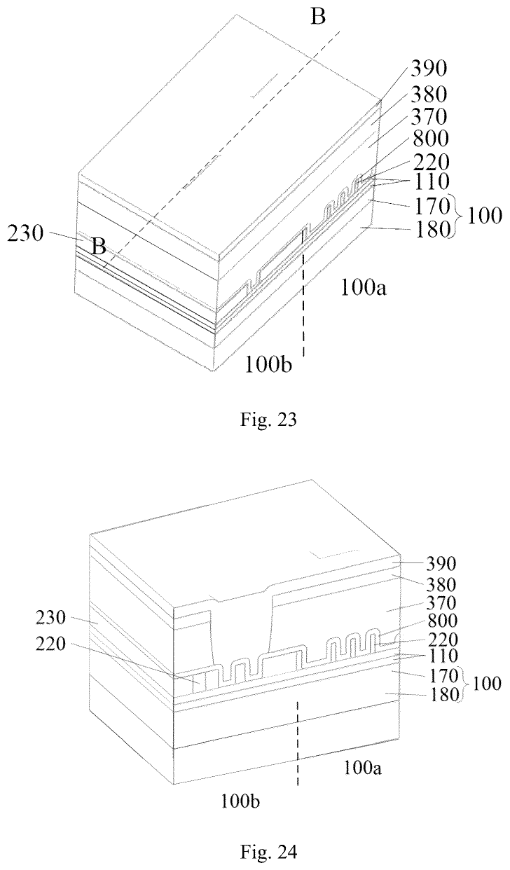

Referring to FIGS. 23 and 24, FIG. 24 is a cross-sectional view of FIG. 23 along the BB direction. A separation material layer 390 filling the third separation openings 970 is formed.

The separation material layer 390 is used to form the third separation structures 960.

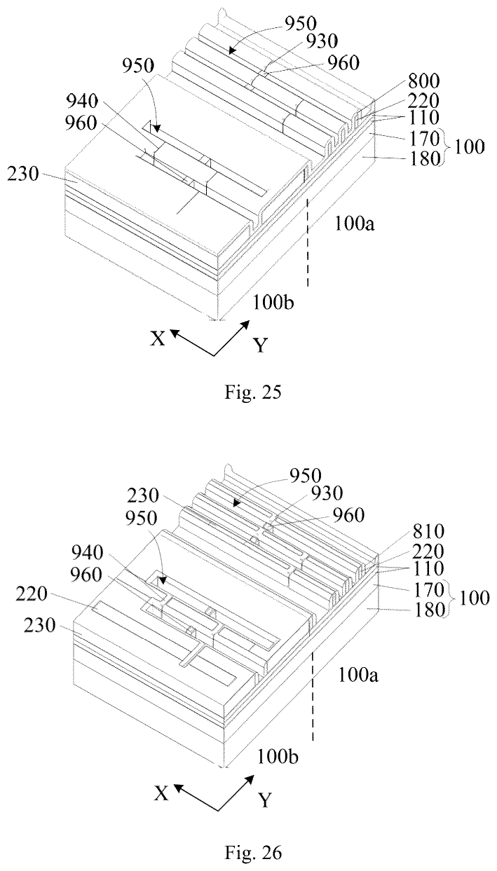

Referring to FIG. 25, after forming the separation material layer 390 filling the third separation openings 970, the method further includes removing the fourth protective layer 370, the fifth mask layer 380, and portions of the separation material layer 390 higher than the second spacer material layer 800.

Referring to FIG. 26, the second spacer material layer 800 on tops of the second core layers 220, the third core layers 230, and the base 100 is removed. Portions of the second spacer material layer 800 on sidewalls of the second core layers 220 and the third core layers 230 are retained as the second spacers 810. Portions of the second spacer material layer 800 below the third separation material layer 390 in the trenches 950 surrounded by the second spacer material layer 800 are retained to form the third separation structures 960.

In some embodiments, a dry etching process is used to remove the second spacer material layer 800 on the tops of the second core layers 220, the third core layers 230, and the base 100.

The dry etching process is an anisotropic etching process. Therefore, by selecting the dry etching process, it is beneficial to reduce the damage to the second core layers 220 and the third core layers 230. At the same time, dry etching is more directional, which is beneficial to improve the sidewall morphology quality and dimensional accuracy of the second spacers 810.

In some embodiments, in the step of removing the second spacer material layer 800 on the tops of the second core layers 220, the third core layers 230, and the base 100, the separation material layer 390 above the tops of the second core layers 220 and the third core layers 230 is also removed. Portions of the separation material layer 390 in the third separation openings 970 are retained as the third separation structures 960 for subsequent pattern transfer to the target material layer 170.

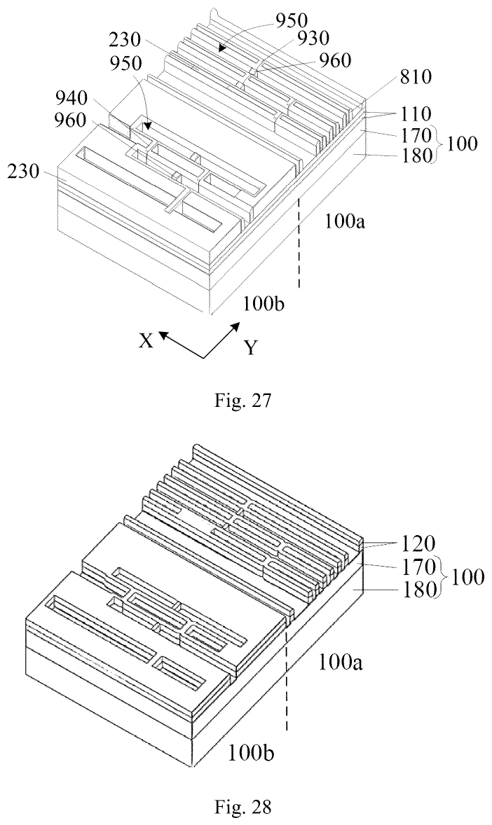

Referring to FIG. 27, the second core layers 220 are removed.

The second core layers 220 are removed to prepare for patterning the target material layer 170 in the first area 100a and the second area 100b using the second spacers 810 and the third core layers 230 as a mask.

Optionally, the second core layers 220 are removed by wet etch.

The wet etching process has the characteristic of isotropic etching, which is conducive to clean removal of the second core layers 220. Moreover, the cost of the wet etching process is relatively low, and the operation steps are simple. It may also achieve a large etching selectivity ratio, which is conducive to reducing the damage to the second spacers 810 during removal of the second core layers 220.

In some embodiments, in the step of removing the second core layers 220 by a wet etching process, the etching solution of the wet etching process includes one or more of potassium hydroxide (KOH) solution, 2,4,5-trihydroxymethamphetamine (THMA) solution, and standard clean 1 (SC1) solution.

In some embodiments, the second core layers 220 include an undoped silicon material, and the third core layers 230 is a doped silicon material. KOH solution or THMA solution has a higher etching rate for undoped silicon and almost no etching rate for doped (especially boron ion doped) silicon. Therefore, using KOH solution or THMA solution as an etching solution may reduce the damage to the third core layers 230 while removing the second core layers 220. And alkaline solutions such as KOH solution, SC1 solution, and THMA solution have almost no etching rate for the third separation structures 960 and the second spacers 810 formed by the separation material layer 390. This makes the process of removing the second core layers 220 almost have no impact on other components in the entire pattern transfer process.

In some embodiments, the second core layers 220 are removed, while the third core layers 230 in the second area 100b and the first area 100a are retained.

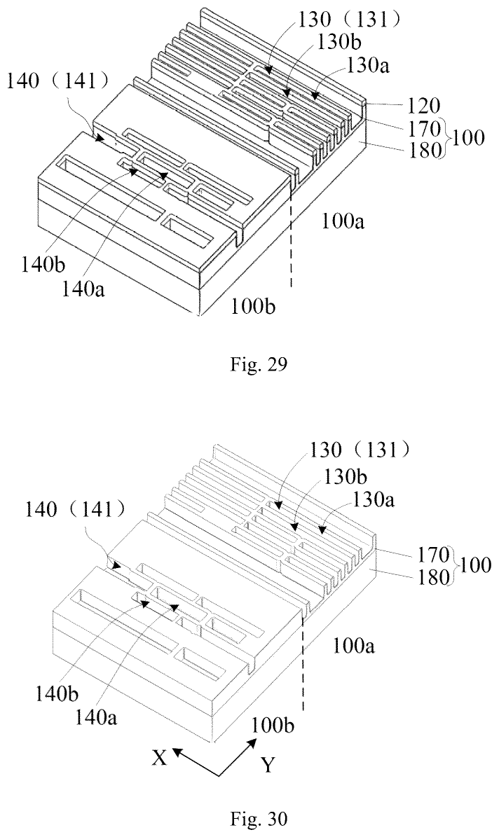

Referring to FIGS. 28 and 29, the second spacers 810 and the third core layers 230 are used as a mask to pattern the target material layer 170. The first target structures 131 in the first area 100a and second target structures 141 in the second area 100b are formed.

In some embodiments, the second spacers 810, the third core layers 230, the first separation structures 930, the second separation structures 940, and the third separation structures 960 are used as a mask to pattern the target material layer 170, forming first target structures 131 in the first area 100a and second target structures 141 in the second area 100b.

In some embodiments, the first core layers 410 are formed in the first area 100a. The first spacers 510 covering sidewalls of the first core layers 410 are formed. The first protective layer 610 is formed on the second core material layer 200 in the second area 100b.

The first protective layer 610 has separate first protective layer openings 620 extending along the first direction and arranged in parallel along the second direction. The second core material layer 200 is patterned using the first spacers 510 and the first protective layer 610 as a mask to form the second core layers 220. For the first area 100a, the second spacers 810 covering sidewalls of the second core layers 220 are formed, and the target material layer 170 is patterned using the second spacers 810 as a mask. The above processes use SAQP. The SAQP process may form the first target structures 131 with a smaller pitch. For the second area 100b, a part of the second core layers 220 in the second area 100b is modified by using the second protective layers 710 as a mask. The part of the second core layers 220 is transformed into the third core layers 230 having an etching selectivity ratio with the second core layers 220. The second spacers 810 covering sidewalls of the second core layers 220 and the third core layers 230 are formed. The target material layer 170 is patterned by using the second spacers 810 and the third core layers 230 as a mask. The above processes use SALELE. The second target structures 141 with a larger pitch may be formed by using SALELE. By integrating the SAQP process and the SALELE process, the first target structures 131 with a smaller pitch and the second target structures 141 with a larger pitch are made over the same base 100. It is conducive to meeting more semiconductor process requirements through process integration and improving the design freedom in patterning processes.

In some embodiments, the target material layer 170 is patterned using the second spacers 810 and the third core layers 230 as a mask, forming the first target structure 131 in the first area 100a and the second target structure 141 in the second area 100b. In the step of the above processes, the target material layer 170 is also patterned using the first separation structures 930 and the second separation structures 940 as a mask or partial mask, obtaining portions of the target material layer 170 that correspond to the first separation structures 930 and separate the first target structures 131 in the first direction, and portions of the target material layer 170 that correspond to the second separation structures 940 and separate the second target structures 141 in the first direction.

In some embodiments, in the step of patterning the target material layer 170 with the second spacers 810 and the third core layers 230 as a mask and forming the first target structures 131 in the first area 100a and the second target structures 141 in the second area 100b, the target material layer 170 is also patterned with the third separation structures 960 as a mask, obtaining portions of the target material layer 170 that correspond to the third separation structures 960 and separate the first target structures 131 and separating the second target structures 141 in the first direction.

In some embodiments, in the step of patterning the target material layer 170 with the second spacers 810 and the third core layers 230 as a mask, a dielectric layer is patterned with the second spacers 810 and the third core layers 230 as a mask to form first trenches 130 and second trenches 140 in the dielectric layer.

The first trenches 130 provide space for formation of first metal lines, and the second trenches 140 provide space for formation of second metal lines.

Optionally, portions of the target material layer 170 obtained by pattern transfer from the third core layers 230 in the first area 100a may separate the first trenches 130 along the first direction. It achieves the design freedom of the first trenches 130 in the first direction. It does not transfer a pattern to a position of the target material layer 170 where the first trench 130 is not required when transferring patterns to form the first trenches 130. The process is simple and efficient.

The first trenches 130 may be divided into A-type first trenches 130a and B-type first trenches 130b that are spaced apart from each other. The A-type first trenches 130a are the first trenches 130 corresponding to the fourth core layers 240, and the B-type first trenches 130b are the first trenches 130 corresponding to the trenches 950 surrounded by the second spacer material layer 800 of the fourth core layers 240.

The second trenches 140 may also be divided into A-type second trenches 140a and B-type second trenches 140b. The A-type second trenches 140a are the second trenches 140 corresponding to the second core layers 220, and the B-type second trenches 140b are the second trenches 140 corresponding to the trenches 950 surrounded by the second spacer material layer 800 on sidewalls of the second core layers 220 and the third core layers 230.

In some embodiments, the dielectric layer corresponding to the first separation structures 930 separates the A-type first trenches 130a in the first direction. The dielectric layer corresponding to the second separation structures 940 separates the A-type second trenches 140a in the first direction. The dielectric layer corresponding to the third separation structures 960 separates the B-type first trenches 130b and the B-type second trenches 140b in the first direction.

Optionally, referring to FIG. 28, the step of patterning the target material layer 170 with the second spacers 810 and the third core layers 230 as a mask includes patterning the mask material layer 110 with the second spacers 810 and the third core layers 230 as a mask to form a second pattern transfer layer 120.

The second pattern transfer layer 120 is used as an etching mask for patterning the target material layer 170.

In some embodiments, after forming the second pattern transfer layer 120, and before patterning the target material layer 170 with the second pattern transfer layer 120 as a mask, the method further includes removing the second spacers 810 and the third core layers 230 to prepare for patterning the target material layer 170 with the second pattern transfer layer 120 as a mask.

Referring to FIG. 29, the target material layer 170 is patterned with the second pattern transfer layer 120 as a mask.

The pattern of the second spacers 810 and the third core layers 230 is transferred to the target material layer 170 through the second pattern transfer layer 120, which is conducive to improving the accuracy of the pattern transfer. It improves the size accuracy of the first target structures 131 and the second target structures 141.

Optionally, the target material layer 170 is patterned using the second pattern transfer layer 120 as a mask by using an etching process. The second pattern transfer layer 120 is thinned in the step of patterning the target material layer 170. For example, a silicon oxide layer in the second pattern transfer layer 120 may be removed.

Referring to FIG. 30, after forming the first target structures 131 and the second target structures 141, the method further includes removing the second pattern transfer layer 120.

Removing the second pattern transfer layer 120 prepares for formation of the first metal lines and the second metal lines.

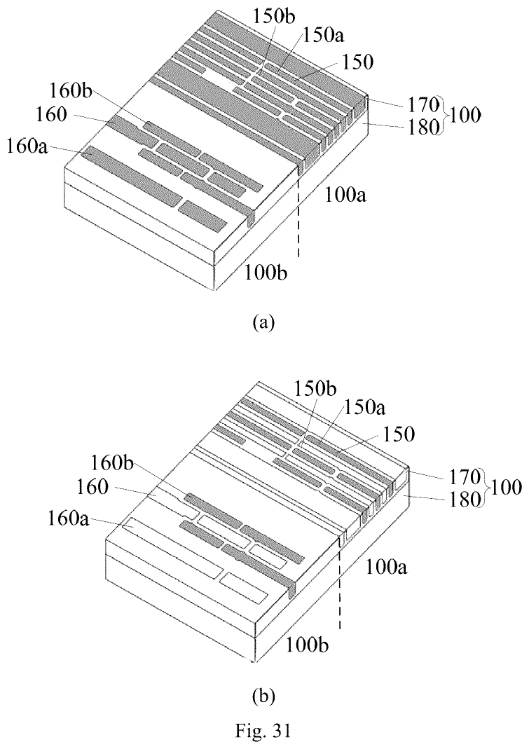

Referring to FIG. 31, after forming the first target structures 131 in the first area 100a and the second target structures 141 in the second area 100b, the formation method further includes forming first metal lines 150 in the first trenches 130 and second metal lines 160 in the second trenches 140.

The first metal lines 150 and the second metal lines 160 are metal interconnects in a back-end-of-line (BEOL) process.

Optionally, the dielectric layer transferred from the third core layers 230 in the first area 100a may separate the first metal lines 150 in the first trenches 130 along a first direction. The design freedom of the first metal line 150 in the first direction is achieved. Moreover, during the transfer of patterns to form the first metal lines 150, patterns are not transferred at positions where the first metal lines 150 are not required in the dielectric layer. Without adding masks and process steps, certain redundant first metal lines 150 in the first area 100a are removed. It reduces the capacitance among some of the first metal lines 150 that are made through SAQP in the first area 100a, thereby improving the performance of the circuit and chip of the semiconductor structure (e.g., better standard test condition (STC) performance). The process is simple and efficient. Therefore, it enables the efficient and low-cost formation of the target structure as shown in part (a) of FIG. 33.

Part (b) of FIG. 31 schematically distinguishes between different types of the first metal lines 150 and the second metal lines 160 shown at part (a) of in FIG. 31.

Optionally, the first metal lines 150 may be divided into A-type first metal lines 150a (as shown by the black-filled first metal lines 150 in the first area 100a of part (b) in FIG. 31) and B-type first metal lines 150b (as shown by the white-filled first metal lines 150 in the first area 100a of part (b) in FIG. 31), which are arranged separately from each other. The A-type first metal lines 150a are metal lines corresponding to the second core layers 220 in the first area 100a. The B-type first metal lines 150b are metal lines corresponding to the trenches 950 surrounded by the second spacer material layer 800 of the second core layers 220 in the first area 100a.

Similarly, the second metal lines may also be divided into A-type second metal lines 160a (as shown by the white-filled second metal lines 160 in the second area 100b of part (b) in FIG. 31) and B-type second metal lines 160b (as shown by the black-filled second metal lines 160 in the second area 100b of part (b) in FIG. 31). The A-type second metal lines 160a are the metal lines corresponding to the second core layers 220 in the second area 100b, and the B-type second metal lines 160b are the metal lines corresponding to the trenches 950 surrounded by the second spacer material layer 800 on sidewalls of the second core layers 220 and the third core layers 230 in the second area 100b. The A-type second metal lines 160a and the B-type second metal lines 160b may be arranged at intervals from each other and the pitch, width, and length may be adjusted. The design of the second metal lines 160 is more flexible than that of the first metal lines 150.

Correspondingly, in some embodiments, the dielectric layer corresponding to the first separation structures 930 separates the A-type first metal lines 150a along the first direction. The dielectric layer corresponding to the second separation structures 940 separates the A-type second metal lines 160a along the first direction. The dielectric layer corresponding to the third separation structures 960 separates the B-type first metal lines 150b and B-type second metal lines 160b along the first direction.

A dielectric layer is an inter metal dielectric (IMD) layer. The dielectric layer is used to achieve electrical isolation between metal interconnect lines in a BEOL process.

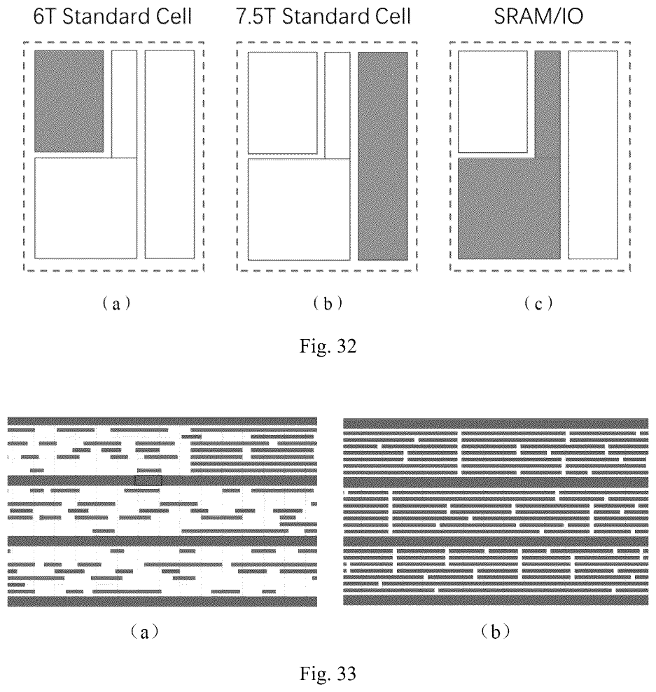

Exemplarily, as shown in FIG. 32, formation methods for some embodiments are illustrated. A 6 T standard cell area, a 7.5 T standard cell area, and an SRAM/input-output area (SRAM/IO) are formed over the base. The black area marks a corresponding device area.

Optionally, in the 6 T standard cell area at part (a) of FIG. 32, the metal pitch reaches about 30 nm, and uniform metal lines for routing and wider power rails are required. Thus, SAQP may be used in the formation process. In the 7.5 T standard cell area at part (b) of FIG. 32, the metal pitch is around 40 nm, and uniform metal lines for routing and wider power rails are required. Thus, SALELE may be used in the formation process. In the SRAM/IO area at part (c) of FIG. 32, the metal pitch is larger than 50 nm, and there are no clear layout rules for metal routing. Thus, SALELE may be used in the formation process. Therefore, by combining SAQP and SALELE, the 6 T standard cell areas, 7.5 T standard cell areas, and SRAM/IO areas that have different pitch requirements may be achieved over the same base.

Although the present disclosure is illustrated as above, the present disclosure is not limited thereto. Any person skilled in the art may make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a base, wherein the base include a substrate and a target material layer on the substrate, a second core material layer and a first core material layer on the second core material layer are formed over the base, the base further includes a first area for forming a plurality of first target structures, and a second area for forming a plurality of second target structures, the plurality of first target structures and the plurality of second target structures extend along a first direction, and a pitch of adjacent first target structures of the plurality of second target structures is less than or equal to a pitch of adjacent second target structures of the plurality of second target structures;
patterning the first core material layer and forming a plurality of first core layers that are separate in the first area, extend along the first direction, and are arranged in parallel along a second direction, the first direction being perpendicular to the second direction;
forming a plurality of first spacers covering sidewalls of the plurality of first core layers;
removing the plurality of first core layers;
forming a first protective layer on the second core material layer in the second area, wherein the first protective layer is formed with a plurality of first protective layer openings that are separate, extend along the first direction, and are arranged in parallel along the second direction;
using the plurality of first spacers and the first protective layer for masking to pattern the second core material layer and forming a plurality of second core layers;
removing the plurality of first spacers and the first protective layer;
forming a plurality of second protective layers on the plurality of second core layers, wherein the plurality of second protective layers are separately arranged in the second area;
using the plurality of second protective layers for masking to modify the plurality of second core layers exposed in the second area and forming a plurality of third core layers having an etching selectivity ratio with remaining second core layers of the plurality of second core layers;
removing the plurality of second protective layers;
forming a plurality of second spacers covering sidewalls of the plurality of second core layers and the plurality of third core layers;
removing the plurality of second core layers; and
patterning the target material layer using the plurality of second spacers and the plurality of third core layers for masking and forming the plurality of first target structures in the first area and the plurality of second target structures in the second area.

2. The method for forming the semiconductor structure according to claim 1, wherein:
in a step of providing the base, the target material layer includes a dielectric layer, the plurality of first target structures include a plurality of first trenches, and the plurality of second target structures include a plurality of second trenches;
in a step of patterning the target material layer using the plurality of second spacers and the plurality of third core layers for masking, the dielectric layer is patterned using the plurality of second spacers and the plurality of third core layers for masking and the plurality of first trenches and the plurality of second trenches are formed in the dielectric layer; and
after forming the plurality of first target structures in the first area and the plurality of second target structures in the second area, the method according to claim 1 further comprises forming a plurality of first metal lines in the plurality of first trenches and forming a plurality of second metal lines in the plurality of second trenches.

3. The method for forming the semiconductor structure according to claim 1, wherein in a step of providing the base, the first area comprises a logic device area and the second area comprises a peripheral device area.

4. The method for forming the semiconductor structure according to claim 3, wherein a thickness of a gate oxide layer in the logic device area is less than a thickness of a gate oxide layer in the peripheral device area.

5. The method for forming the semiconductor structure according to claim 1, wherein:
a minimum pitch of the adjacent first target structures of the plurality of first target structures is 24 nm to 38 nm; and
a minimum pitch of the adjacent second target structures of the plurality of second target structures is 38 nm to 200 nm.

6. The method for forming the semiconductor structure according to claim 1, wherein:
a step of patterning the first core material layer comprises forming a plurality of first mask layers that are on the first core material layer and separate in the first area;
the first core material layer is patterned through the plurality of first mask layers to form the plurality of first core layers that are separated in the first area; and
after forming the plurality of first core layers, the method according to claim 1 further comprises removing the plurality of first mask layers.

7. The method for forming the semiconductor structure according to claim 1, wherein a step of forming the plurality of first spacers covering the sidewalls of the first core layers comprises:
forming a first spacer material layer covering the sidewalls and tops of the first core layers and above the second core material layer; and
removing portions of the first spacer material layer on the tops of the plurality of first core layers and above the second core material layer, and retaining portions of the first spacer material layer on the sidewalls of the plurality of first core layers as the plurality of first spacers.

8. The method for forming the semiconductor structure according to claim 1, wherein a step of forming the first protective layer on the second core material layer in the second area comprises:
forming a first protective material layer covering the second core material layer and the plurality of first spacers; and
patterning the first protective material layer in the second area, removing the first protective material layer in the first area, and forming separate portions of the first protective material layer in the second area as the first protective layer.

9. The method for forming the semiconductor structure according to claim 1, wherein in a step of modifying the plurality of second core layers exposed in the second area using the plurality of second protective layers for masking, ion implantation is performed in the plurality of second core layers exposed in the second area using the plurality of second protective layers for masking, and the plurality of third core layers having the etching selectivity ratio with the plurality of second core layers are formed.

10. The method for forming the semiconductor structure according to claim 9, wherein:
in a step of providing the base, a material of the second core material layer comprises one or more of amorphous silicon, polycrystalline silicon, single crystal silicon, silicon oxide, advanced patterned film materials, spin-on carbon and silicon carbide; and
in a step of performing the ion implantation in the plurality of second core layers exposed in the second area using the plurality of second protective layers for masking, ions implanted in the ion implantation include one or more of boron, phosphorus, arsenic, boron chloride, boron dichloride and carbon.

11. The method for forming the semiconductor structure according to claim 1, wherein:
in a step of forming the plurality of second protective layers on the plurality of second core layers, the plurality of second protective layers cover the plurality of second core layers in the first area; or
in a step of forming the plurality of second protective layers on the plurality of second core layers, a plurality of second protective layer openings are formed in the plurality of second protective layers in the first area, wherein the plurality of second protective layer openings expose the plurality of second core layers and extend along the first direction; and
in a step of modifying the plurality of plurality of second core layers exposed in the second area using the plurality of second protective layers for masking, the plurality of second core layers exposed by the plurality of second protective layer openings in the first area are modified to form the plurality of third core layers in the second area.

12. The method for forming the semiconductor structure according to claim 11, wherein
in the step of forming the plurality of second protective layers on the plurality of second core layers, the plurality of second protective layer openings exposing the plurality of second core layers are formed in the plurality of second protective layers in the first area, and the plurality of second protective layer openings extend along the first direction; and
the step of forming the plurality of second protective layers on the plurality of second core layers comprises:
forming a second protective material layer covering the plurality of second core layers; and
patterning the second protective material layer, forming the plurality of second protective layers that are on the plurality of second core layers and separate in the second area, and forming the plurality of second protective layers covering the plurality of second core layers and having the plurality of second protective layer openings exposing the plurality of second core layers in the first area.

13. The method for forming the semiconductor structure according to claim 1, wherein in a step of modifying the plurality of second core layers exposed in the second area using the plurality of second protective layers for masking, a size of the remaining second core layers along the second direction is 35 nm to 200 nm, a pitch of the remaining second core layers along the second direction is 76 nm to 200 nm, a size of the plurality of third core layers along the second direction is 35 nm to 200 nm, and a pitch of the plurality of third core layers along the second direction is 76 nm to 200 nm.

14. The method for forming the semiconductor structure according to claim 1, wherein a step of forming the plurality of second spacers covering the sidewalls of the plurality of second core layers and the plurality of third core layers comprises:
forming a second spacer material layer covering the sidewalls and tops of the plurality of second core layers and the plurality of third core layers, and a top of the base; and
removing portions of the second spacer material layer on the tops of the plurality of second core layers and the plurality of third core layers, and the top of the base, and retaining portions of the second spacer material layer on the sidewalls of the plurality of second core layers and the plurality of third core layers as the plurality of second spacers.

15. The method for forming the semiconductor structure as claimed in claim 1, wherein:
in a step of providing the base, an etching stop layer is formed between the first core material layer and the second core material layer;
before forming the first protective layer on the second core material layer in the second area, the method according to claim 1 further includes patterning the etching stop layer using the plurality of first spacers for masking and forming a first pattern transfer layer;
in a step of patterning the second core material layer using the plurality of first spacers and the first protective layer for masking and forming the plurality of second core layers, the second core material layer in the first area is patterned using the first pattern transfer layer for masking and the plurality of second core layers are arranged separated in the first area; and
after forming the plurality of second core layers, the method according to claim 1 further includes removing the first pattern transfer layer.

16. The method for forming the semiconductor structure according to claim 1, wherein:
the plurality of second core layers are removed by a wet etching process; and
an etching solution of the wet etching process comprises one or more of a potassium hydroxide (KOH) solution, a 2,4,5-trihydroxymethamphetamine (THMA) solution, and a standard clean 1 (SC1) solution.

17. The method for forming the semiconductor structure according to claim 1, wherein:
in a step of providing the base, a mask material layer is formed between the target material layer and the second core material layer;
a step of patterning the target material layer using the plurality of second spacers and the plurality of third core layers for masking comprises:
patterning the mask material layer using the plurality of second spacers and the plurality of third core layers for masking to form a second pattern transfer layer;
patterning the target material layer using the second pattern transfer layer for masking; and
after forming the plurality of first target structures and the plurality of second target structures, the method according to claim 1 further comprises removing the second pattern transfer layer.

18. The method for forming the semiconductor structure according to claim 17, wherein after forming the second pattern transfer layer and before patterning the target material layer using the second pattern transfer layer for masking, the method further comprises removing the plurality of second spacers and the plurality of third core layers.

19. The method for forming the semiconductor structure according to claim 1, wherein:
after removing the plurality of second protective layer and before forming the plurality of second spacers covering the sidewalls of the plurality of second core layers and the plurality of third core layers, the method according to claim 1 further comprises:
patterning part of the plurality of second core layers in the first area, and part of the plurality of second core layers and the plurality of third core layers in the second area, and forming a plurality of first separation openings that cut off the plurality of second core layers in the first area in the first direction, and a plurality of second separation openings that cut off the plurality of second core layers in the second area in the first direction;
in a step of forming the plurality of second spacers covering the sidewalls of the second core layers and the third core layers, the plurality of second spacers further cover sidewalls of the plurality of first separation openings and the plurality of second separation openings, second spacers of the plurality of second spacers on opposite sidewalls of the plurality of first separation openings are in contact with each other to form a plurality of first separation structures, and second spacers of the plurality of second spacers on opposite sidewalls of the plurality of second separation openings are in contact with each other to form a plurality of second separation structures; and
in a step of patterning the target material layer using the plurality of second spacers and the plurality of third core layers for masking and forming the plurality of first target structures in the first area and the plurality of second target structures in the second area, the target material layer is patterned using the plurality of first separation structures and the plurality of second separation structures for masking, portions of the target material layer corresponding to the plurality of first separation structures are obtained to separate the plurality of first target structures in the first direction, and portions of the target material layer corresponding to the plurality of second separation structure are obtained to separate the plurality of second target structures in the first direction.

20. The method for forming the semiconductor structure according to claim 14, wherein:
in a step of forming the second spacer material layer covering the sidewalls and the tops of the plurality of second core layers and the plurality of third core layers, and the top of the base, portions of the second spacer material layer on opposite sidewalls of the plurality of second core layers and the plurality of third core layers surround and form a plurality of trenches;
after forming the second spacer material layer covering the sidewalls and tops of the plurality of second core layers and the plurality of third core layers, and the top of the base, and before removing the portions of the second spacer material layer on the tops of the plurality of second core layers and the plurality of third core layers, and the top of the base, the method further comprises:
forming a plurality of third separation structures extending along the second direction and contacting the plurality of second spacers in the plurality of trenches in the first area and the second area, wherein the plurality of third separation structures separate the plurality of trenches in the first direction; and
in a step of patterning the target material layer using the plurality of second spacers and the plurality of third core layers for masking and forming the plurality of first target structures in the first area and the plurality of second target structures in the second area, the target material layer is further patterned using the plurality of third separation structures for masking and portions of the target material layer corresponding to the plurality of third separation structures are obtained to separate the plurality of first target structures and the plurality of second target structures in the first direction.
